(19) United States
(12) Patent Application Publication
(10) Pub. No.: US 2025/0264814 A1
(43) Pub. Date: Aug. 21, 2025

(54) OPTIMIZATION OF A METROLOGY ALGORITHM FOR EXAMINATION OF SEMICONDUCTOR WAFERS

(71) Applicant: Applied Materials Israel Ltd., Rehovot (IL)

(72) Inventors: Tal BEN-SHLOMO, Givatayim (IL); Nir BILLFELD, Kiryat Ata (IL); Ilan BEN-HARUSH, Tel-Aviv (IL); Noam TEOMIM, Rehovot (IL); Anna LEVANT, Rehovot (IL); Dror ALUMOT, Tel-Aviv (IL); Mor BARAM, Nes Ziona (IL)

(21) Appl. No.: 18/443,236

(22) Filed: Feb. 15, 2024

(51) Int. Cl. G03F 7/00

(52) U.S. Cl. CPC G03F 7/706845; G03F 7/706837; G03F 7/706841

(57) ABSTRACT

A method and system for optimizing a metrology algorithm used by an inspection tool for inspecting predetermined sites of a semiconductor wafer during fabrication so as to allow repetitive and consistent inspection for multiple sites of the wafer by both a single inspection tool of a given type using the metrology algorithm and also across a fleet of different inspection tools of the same type using the metrology algorithm. An aggregate loss function is computed from a sum of component loss functions. In one aspect, each component loss function is amplified by a non-linear function that applies a positive gain for in-range measurements and for out-of-range measurements, applies a steep penalty that swamps any cumulative gains associated with other component loss functions. In another aspect, distribution-based metrics are used to measure similarity between two distributions of measurements for multiple locations across two different tools.

### FIELD OF THE INVENTION

The presently disclosed subject matter relates, in general, to the field of inspection of a semiconductor wafer, and more specifically, to metrology recipe optimization for wafer inspection.

### BACKGROUND OF THE INVENTION

Current demands for high density and performance associated with ultra large-scale integration of fabricated devices require submicron features, increased transistor and circuit speeds, and improved reliability. As semiconductor processes progress, pattern dimensions such as line width, and other types of critical dimensions, are continuously shrunken. Such demands require formation of device features with high precision and uniformity, which, in turn, necessitates careful monitoring of the fabrication process, including automated examination of the devices while they are still in the form of semiconductor wafers.

Examination can be provided by using non-destructive examination tools during or after manufacture of the specimen to be examined. Examination generally involves generating certain output (e.g., images, signals, etc.) for a specimen by directing light or electrons to the wafer and detecting the light or electrons from the wafer. A variety of non-destructive examination tools includes, by way of non-limiting example, scanning electron microscopes, atomic force microscopes, optical inspection tools, etc.

Semiconductors such as integrated circuits are manufactured in large wafers on which multiple identical circuits are fabricated. During fabrication, discrete circuits on the same wafer are subjected to a series of inspections in order to establish circuit integrity and operability. These inspections include, among others, metrology tests that establish that circuit patterns conform to design specifications. Metrology inspection tools may employ a so-called Critical Dimension Scanning Electron Microscope (CD-SEM) for measuring the dimensions of the fine patterns formed on a semiconductor wafer. CD-SEM is mainly used in the manufacturing lines of electronic devices of semiconductors. Within the context of wafer inspection, a recipe is a program (a collection of procedures, processing methods, parameters and input data) input into an inspection system such as CD-SEM. The term ‘recipe’ is also used to describe a set of stored parameters for a particular process step during wafer fabrication, such as gas flow temperature and pressure. In order to distinguish between the two types of recipes, we will refer to them as either a ‘metrology recipe’ or a ‘fabrication recipe’, as appropriate. The condition and procedures of the dimensional measurement are input into a recipe in advance. When the measurement process is started, the CD-SEM will automatically load the sample wafer into the CD-SEM and measure the desired positions on the sample.

Wafer inspection can include a plurality of inspection steps. The manufacturing process of a semiconductor device can include various procedures such as etching, depositing, planarization, growth such as epitaxial growth, implantation, etc. The inspection steps can be performed multiple times, for example after certain process procedures, and/or after the manufacturing of certain layers, or the like. Additionally, or alternatively, each inspection step can be repeated multiple times, for example for different wafer locations, or for the same wafer locations with different settings.

Inspection processes are used at various steps during wafer fabrication to detect and classify defects on specimens, as well as perform metrology related operations. Effectiveness of inspection can be improved by automatization of process(es) such as, for example, defect detection, Automatic Defect Classification (ADC), Automatic Defect Review (ADR), image segmentation, automated metrology-related operations, etc.

Automated inspection systems ensure that the parts manufactured meet the quality standards expected and provide useful information on adjustments that may be needed to the manufacturing tools, equipment, and/or compositions, depending on the type of defects identified.

By way of example, metrology operations can be performed on the specimen to measure one or more characteristics of the structural features/elements formed on the specimen, such as, e.g., dimensions (e.g., line widths, line spacing, contacts diameters, size of the element, edge roughness, gray level statistics, etc.), shapes of elements, distances within or between elements, related angles, and overlay information associated with elements corresponding to different design levels, etc. Such measurements can be used to evaluate the performance of the processing step(s) during which the features are fabricated. For instance, if some of the measurements of the specimen are unacceptable (e.g., outside a predetermined range or threshold), the measurements may be used to alter one or more parameters of the processing step(s) in order that subsequent specimens manufactured by the same processing step(s) will be within range.

Metrology operations are performed by a metrology tool using metrology recipes. A metrology recipe is typically created during a recipe setup phase and defines one or more metrology algorithms each pertaining to a different metrology application. The metrology recipe, upon being created, can be used by a metrology tool for performing metrology operations on a semiconductor specimen during runtime examination.

A metrology algorithm typically requires enumeration of a large group of algorithm parameters that serve as input arguments to the algorithm and are conventionally tuned manually, e.g., by an application engineer. The number of algorithm parameters and their definition are a function of the metrology algorithm. The algorithms are, of course, computer programs whose parameters are set by the end-user prior to use. Thus, the end-user decides what metrology algorithm to use for any given measurement and specifies the value each parameter takes. The metrology algorithm uses the defined parameters to determine the dimension of a specified feature. Each metrology algorithm in combination with the parameters defined by the end-user are what together constitutes the recipe. In this respect, the recipe can be compared to a cake recipe: there are many conceptual similarities. Thus, a sponge cake, a madeira cake and a Victoria sandwich all contain eggs, sugar and flour and the two latter cakes both contain fat. But these ingredients are required in different proportions and the mixture must be baked for different amounts of time. One user may be concerned to limit cholesterol and may wish to use fewer eggs than the textbook recipe requires. Another user may wish to cut down on sugar, and so on. But playing around with the ingredients is not a trivial exercise since reducing the amount of sugar may require a compensatory adjustment to other ingredients, or maybe cooking temperature or time. In other words, if the ingredients and their respective quantities are analogous to the parameters of the selected metrology algorithm, then like the cake ingredients, the parameters of the metrology algorithm are interrelated in the sense that changing one parameter may require adjustment of another parameter in order to achieve optimal results. Moreover, the more parameters a recipe includes, the more difficult it is to fine-tune, particular bearing in mind that conventionally the adjustments are made manually by trial-and-error. Such manual tuning is limited to a small number of parameters and relies on personal experience and proficiency, thus is normally time-consuming and prone to error even with a high level of expertise. In addition, as semiconductor fabrication processes continue to advance, semiconductor devices are developed with increasingly complex structures and shrinking feature dimensions, which requires tighter specs of the metrology metrics such as precision and matching to be met. Application engineers face increasing challenges to tune the parameters in order to meet the specs as well as properly balance between the various metrology metrics.

It is known to use off-the-shelf tools to optimize parameters, i.e. provide a vector of parameters, which when fed back to the optimization algorithm minimizes cost to an acceptable level. One such tool is ‘Optuna’, which may be used to minimize or maximize an objective function Z=ax+by where a, b are constraints and x, y are variables. The constraints are linear equations, which define limits or boundaries for which values of the variables are valid. Objective functions may, for example, represent a profit that is to be maximized or a cost that is to be minimized. Optuna is one of many similar parameter optimization tools, such as Ray Tune, HyperOpt, Scikit-Optimize among others.

In order to tune the parameters for purpose of meeting the specs, a sufficiently comprehensive image dataset is required for evaluating with respect to the metrology metrics. However, such datasets are often very difficult to obtain. By way of example, in order to evaluate tool-to-tool matching representative of measurement variance between different tools, images should be acquired by different tools. However, in many cases, there are not always a sufficient number of tools available at the R&D center and/or customer site. Even in cases where there are enough tools, such image acquisition requires placing multiple tools offline in the fab thus causing significant tool-down time and adversely affecting system throughput. In addition, even if the entire fleet of tools is put offline for image acquisition, it is not always guaranteed that the images acquired from the fleet of tools at a given time will necessarily possess the expected variations that may be expected to occur during prolonged use.

### SUMMARY OF THE INVENTION

In accordance with a first aspect of the presently disclosed subject matter, there is provided a computerized method for optimizing a metrology algorithm used by an inspection tool, the method comprising:

acquiring at least one set of images, wherein each set captures a respective site on the wafer and includes different images obtained using different tools or different tool settings;

for each specific feature common to each image in the set of images for which a measurement is required, running the metrology algorithm multiple times, each time with a different respective set of input parameters to obtain multiple measurements each pertaining to the respective specific feature;

for each measurement, providing one or more target measurements, each target measurement relating to a component loss function, Mᵢ that indicates whether each measurement falls within a prescribed range with respect to a metrology metric relating to said component loss function;

defining an aggregate loss function of the form:

$$Loss = {\sum }_{i} {ω}_{i} \cdot {M}_{i}$$

wherein at least one of the component loss functions relates to tool matching; and
ωᵢ is a coefficient; and
optimizing the metrology algorithm to obtain an optimal set of input parameters, which when applied to the metrology algorithm produces measurements that are therefore consistent when made by a single inspection tool of a given type or by different inspection tools of the same given type;
wherein optimizing the metrology algorithm includes:
amplifying each component loss function Mᵢ by a non-linear function that compares an actual value of the component loss function Mᵢ with the respective target measurement and applies a positive gain for in-range measurements whose difference from the respective target measurement is less than a prescribed threshold, while for out-of-range measurements whose difference from the respective target measurement exceeds said threshold, applies a steep penalty that swamps any cumulative gains associated with other component loss functions.

Having multiple images representing the different scenarios that the metrology algorithm is likely to encounter allows optimizing of the metrology algorithm to derive a set of parameters that yields consistent measurements when applied to the inspection tool or to different inspection tools of similar type. If the set of images is too small, they may provide too narrow a view of variations that do not reflect all the real world variations.

In accordance with this aspect of the present disclosure, the non-linear component loss function Mᵢ applies an amplification function to the aspect we want to optimize. For example, if in previous approaches Mᵢ was a function that described the gap or mis-match between different tools, in the present case it is used in conjunction with another input set to the required (or target) value of the function (e.g. Mᵢ<0.05) to apply an amplification function (Mᵢ) which, if larger than the target, gives a much higher value (penalty) while if below the target, gives a lower value. What this means in practice is that the loss function, which is optimally minimized across all component loss functions, is skewed to an unacceptably high value if any of the component loss functions is out of range. For the purpose of the present disclosure in all its aspects, we are concerned only with minimizing a loss function constructed from multiple component loss functions. Therefore, we will refer throughout to “loss function” rather than “objective functions.”

This aspect of the present disclosure is distinguished over hitherto-proposed approaches in that the loss function is configured to apply a steep penalty for out-of-range samples, and is moderate for in-scope samples. Consequently, the goal of each score function is taken into account and if the value of the current parameter set exceeds the goal, we amplify the penalty. The steep penalty for out-of-range samples can be such that the farther away from scope is the measurement sample, the steeper the penalty for that sample (for example exponentially increasing according to the extent of exceeding the target). In this way, the optimization becomes more effective since it avoids surrounding areas of sets where the targets are not met, and quickly focuses on searching the optimized set in areas where all the targets are satisfied.

The amplification function thus focuses the optimization system on parameter sets that satisfy all the targets for any Mᵢ, yielding better results and faster convergence to this successful parameter set.

One way to achieve this amplification is by composing each of the sub functions described in detail below with an amplification function of the following form:

$${\overline{u}}_{( x )} = \{ \begin{matrix}2 x ( 1 - {e}^{( cx )} + {xe}^{( cx )} & x > 0 \\ x & x < 0\end{matrix} \}$$

where x represents the difference between a component function and the desired goal. For example, if for Sensitivity we aim to be under 0.1 but the parameter set gave a sensitivity score of 0.2, then x=0.1. As can be seen, we apply an exponential factor to the difference causing the value of the score to be very large. This informs the optimization algorithm to avoid seeking other solutions with similar parameter sets and to focus instead on a different parameter set.

However, if we meet the target then the penalty remains unchanged. Thus, if in the above example for Sensitivity, we aim to be under 0.1 and the parameter set gave a sensitivity score of 0.05 then x=−0.05. This means that we are getting a negative penalty which improves the confidence of the system in this solution. In this case, we do not amplify the error so that the optimization algorithm can seek for other solutions in the same area.

The loss function may be minimized using an off-the-shelf parameter optimizer such as Optuna, Ray Tune, HyperOpt, or Scikit-Optimize. Whether or not a custom parameter optimizer is used, its operation is not a feature of the invention, since optimization per se is well-known to those skilled in the art. All parameter optimizers serve to achieve iterative improvement over a specified parameter space. In an initial iteration, a set of parameters values is input (typically by the user) to the metrology algorithm, which determines measurements of a specified critical dimension from a set of images allowing the value of a loss function to be computed. The optimizer then determines a new set of parameter values to be used for the next iteration based on the computed score (loss). This is repeated until the loss function is minimized or is smaller than a specified target.

In accordance with another aspect of the present disclosure, the function used to find similarity between different tools is based not on per location comparison (also known as Correlation) but rather on distribution metrics of samples in all locations that are more flexible to local changes and thus capture the overall trend. This is achieved by:
obtaining respective measurements for multiple locations across two different tools;
creating respective distributions of the measurements for each of the two different tools; and
using distribution-based metrics to measure similarity between the two distributions.

In some embodiments, the algorithm may be implemented by an enhanced metrology inspection tool, which collates the data and produces the images by effecting suitable adjustments to the tool settings or which obtains images that have been previously collated. However, more generally the algorithm may be performed using a suitably programmed standalone computer, which receives the images as input and produces as output an optimized metrology recipe that may then be used in a fleet of inspection tools to produce consistent inspection results across the whole fleet of tools. The images used by the metrology algorithm may be obtained from a single inspection tool or from multiple tools. In the former case, in order to simulate variations in tool settings that are inherent in a practical inspection environment employing multiple inspection tools, tool settings, such as beam focus, stigmatism and so on, of a single tool may be adjusted in order to generate image variations of each inspection site similar to what might be expected were the inspection site to be imaged with different tools. Of course, in the case where the images are derived from multiple inspection tools, these variations will occur naturally without the need for manual or automated adjustment.

### BRIEF DESCRIPTION OF THE DRAWINGS

In order to understand the invention and to see how it may be carried out in practice, embodiments will now be described, by way of non-limiting example only, with reference to the accompanying drawings, in which:

FIG. 1 shows schematically a general scheme for optimization of input parameters for a metrology algorithm;

FIG. 2a shows pictorially use of the present invention in accordance with a first embodiment wherein a final stage of optimization confines the search space to a narrow area wherein all component loss functions are in-scope;

FIG. 2b shows pictorially an intermediate stage where the optimizer searches in an area wherein at least some component loss functions are out-of-scope;

FIG. 3 is a graphical representation showing amplification on a single component loss function associated with precision of measurements;

FIG. 4 shows schematically data flow associated with a graphical user interface for allowing selection of a metrology algorithm and definition of parameters;

FIG. 5 shows schematically a graphical user interface for allowing selection of component loss functions and associated target values and weights;

FIG. 6 shows schematically a standalone computer according to an embodiment of the present disclosure configured to optimize parameters for a metrology algorithm;

FIGS. 7a and 7b are graphical representation showing a pair of distributions of measurements obtained using two different inspection tools, used as a matching metric according to a second embodiment of the invention; and

FIG. 8 shows some of the principal elements in an enhanced inspection system according to an embodiment of the invention used for inspection of a semiconductor specimen.

### DETAILED DESCRIPTION OF EMBODIMENTS

In accordance with different aspects of the present disclosure, there are provided a method and system for optimizing a metrology algorithm used by an inspection tool that may be used for inspecting predetermined sites of a semiconductor wafer during fabrication so as to allow repetitive and consistent inspection for multiple sites of the wafer by both a single inspection tool of a given type using the metrology algorithm and also across a fleet of different inspection tools of the same type using the metrology algorithm. An aggregate loss function is computed from a sum of component loss functions.

In one aspect, each component loss function is amplified by anon-linear function that applies a positive gain for in-range measurements and for out-of-range measurements, applies a steep penalty that swamps any cumulative gains associated with other component loss functions. In another aspect, distribution-based metrics are used to measure similarity between two distributions of measurements for multiple locations across two different tools.

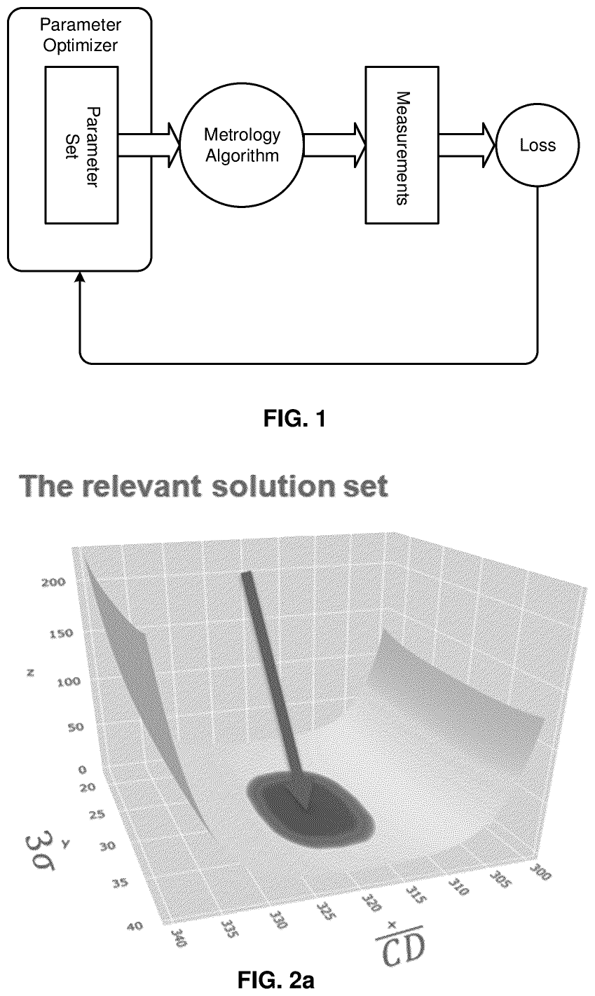

FIG. 1 shows schematically a general scheme for optimization of input parameters for a metrology algorithm. A metrology algorithm receives as input a vector of parameters referred to as a parameter set and uses these parameters to determine measurements of features imaged using an electron microscope. The manner in which the images are obtained is not a feature of the present invention, it being sufficient to note that for any given feature or location there are multiple images derived from one or more inspection tools. For example, multiple images may be obtained from a single inspection tool or from multiple inspection tools of the same type, so as to derive images of a predetermined site of a wafer obtained using different tool parameters such as focus, astigmatism and so on. The different images are analyzed multiple times each time by the same metrology algorithm to determine corresponding values of critical dimensions of an imaged feature. Ideally, the metrology algorithm will produce a consistent measurement result for all images pertaining to the same feature. However, in practice there are deviations, which may be due to tolerances between different inspection tools or to inevitable variations in the same tool. Associated with each measurement there may be one or more component loss functions Mᵢ each relating to a metric associated with the metrology algorithm and which may be used to quantify similarity of measurements. To this end, a target value is provided by the user for each component loss function, Mᵢ that indicates whether the measurement falls within a prescribed range with respect to the metrology metric relating to the specified component loss function. The target value thus serves as a measure of an acceptable tolerance of the metric relating to the corresponding loss function, the lower the target the less deviation between measurements being acceptable. For example, consider two component loss functions denoted by M₁ and M₂ relating to precision and correlation, respectively, and having respective target values T₁ and T₂. We will assume that while high precision is clearly essential, correlation between measurements of the same feature as determined by different inspection tools is even more critical. In this context, it should be noted that precision is internal coherency meaning that the same tool is repeatedly sampled at the same location. Ideally, this should produce the same result. In practice, there are slight variations and the variance with respect to a specified target is the precision score, zero being a perfect match. Consequently, this metric does not relate to the degree of matching between different tools, unlike correlation which does.

To this end, the user defines T₁=10 and T₂=5. In other words, the value of the loss function relating to correlation must be lower than that for precision, since we want to obtain similar if not identical measurements across different inspection tools of the same type.

As is described later, there are usually multiple component loss functions associated with any given metrology algorithm, some of which may relate to precision of measurements, others of which may relates to correlation between measurements using different inspection tools, and so on. At least one of the component loss functions relates to matching between different inspection tools, since a common object of the invention in its various aspects is to optimize the metrology algorithm so that the optimized metrology algorithm will produce consistent measurements across a fleet of different inspection tools of similar type. In practice, as will become clearer when exemplary loss functions are described, two or more component loss functions may need to be fine-tuned in order to achieve optimal matching.

The multiple component loss functions together with their respective target measurements allow a loss function to be defined of the form:

$$Loss = {\sum }_{i} {ω}_{i} \cdot {M}_{i}$$

where: Mᵢ is the i-th component loss function, and
ωᵢ is a coefficient.

In some embodiments, the coefficient ωᵢ defines a relative importance of the respective component loss function within the loss function such that the higher the value of ωᵢ the more effort is exerted by the optimization process to minimize the respective component loss function.

The aggregate loss function produces as its output a number whose value is indicative of the overall performance of the metrology algorithm with respect to the predefined metrics. The lower the value of the aggregate loss function, the better is the metrology algorithm. More specifically, since one or more of the component loss functions measure matching between different inspection tools, a low loss value is indicative of good matching between different inspection tools. The value of the aggregate loss function for each iteration is fed back to the optimizer, which allocates a new parameter set, which when fed to the metrology algorithm, should produce a better result (i.e. lower value of the aggregate loss function) than the previous iteration. This cycle is repeated until the value of the aggregate loss function meets or is less than a defined target.

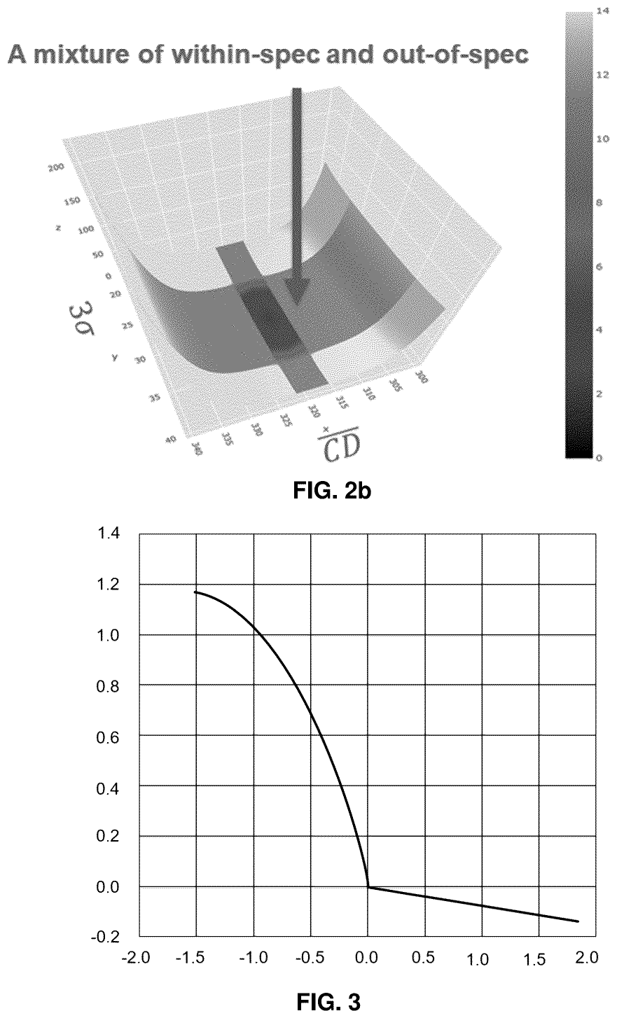

FIG. 2a shows pictorially use of the present invention in accordance with a first embodiment for confining optimization to within a narrow space where all component loss functions are in scope. For ease of illustration and explanation, we relate to a loss function that sums the respective losses for only two component loss functions, denoted by 3σ and C̅D̅ whose values are plotted along mutually orthogonal axes. FIG. 2a depicts the relevant solution set, wherein the optimizer has allocated a set of parameters that, when fed to the metrology algorithm, produces measurements for which the respective component loss functions are both in-spec.

FIG. 2b depicts the situation where there is a mixture of in-spec and out-of-spec measurements. At the right hand side of the figure is a grayscale-chart [that serves to indicate the value of the loss function at any point in space. The lower the value of the loss function, the darker is the shade. This can be understood by denoting the values of the two loss functions by V₁ and V₂ and their respective target values by T₁ and T₂. More generally, for the i-th component loss function, these will be denoted as Vᵢ and Tᵢ.

If Vᵢ>Tᵢ this means that the value of the loss function for this metric is out-of-spec, and we then apply amplification that serves to increase the loss function to such a high value that it swamps the sum of the values of the respective component loss functions for other metrics, even if they are all in-spec. Consequently, the sum of the component loss functions is high and the optimizer allocates a new set of the parameters to the metrology algorithm, so as to generate new component loss functions, this being repeated until the value of the aggregate loss function is within spec. The amplification is typically exponential so as to render an out-of-scope value extremely high. By way of example, we will consider the case where the amplification applied to an out-of-scope component loss function is e^{V}, where e=2.71828 and V is the value of the component loss function.

Referring to FIG. 2a, suppose that acceptable values of the respective loss functions for the two parameters C̅D̅ and 3σ are 10 and 5. In a first iteration, the respective loss functions are:
C̅D̅ V₁=8
3α V₂=6

This means that C̅D̅ is already in scope while 3σ is slightly out-of-scope. The total loss is equal to 14. This is fed to the optimizer and we will suppose that in a second iteration, the respective loss functions are:
C̅D̅ V₁=5
3σ V₂=7

The total loss according to the conventional approach would now be equal to 12, which seems better. But in fact, for C̅D̅ the first result was in-scope for the first iteration (even though its loss function is better, i.e. smaller in the second iteration) while the second measurement for 3σ is more out-of-scope in the second iteration. In other words, the fact that the sum of the loss functions is smaller in the second iteration when using the conventional approach is deceptive, because actually the result of the second iteration is worse.

In accordance with the first aspect of the present disclosure, we correct this by applying the amplification e⁷ to the out-of-scope value of V₂=6 in the first iteration.

$$\overline{CD} {V}_{1} = 8$$

$$3 σ {V}_{2} = 6 \times {e}^{6} = 6 \times 403.4 ≅ 2 , 420$$

The total loss according to the modified approach is now be equal to 2,428, which is drastically worse than the initial values, thus forcing the optimizer to allocate new parameters for feeding to the metrology algorithm. It can thus be seen that the penalty for a single out-of-range measurement exceeds the positive gains for all in-range measurements to an extent that the penalty swamps the positive gains. We reiterate that the manner in which the optimizer allocates new parameters based on the value of the loss function is not a feature of the invention, it being understood that this what optimizers do. In an embodiment of the invention reduced to practice, we used a parameter optimizer in what is referred to as “suggest” mode. The following result was obtained:
C̅D̅ V₁=9
3σ V₂=5

The total loss is now equal to 14 and the values of both loss functions are in scope. Therefore, the corresponding values of C̅D̅ and 3σ shown in FIG. 2a can be read or interpolated from the respective scales of the two parameters and fed to the metrology algorithm.

FIG. 3 is a graphical representation showing amplification on a single component loss function associated with precision of measurements taken at different locations with a single tool, shown in the figure normalized to zero. For example, we might measure the width of a conductor of ideally uniform width at different locations along its length. Denoting each measurement by wᵢ, we can define precision, P, as:

$$P = {\sum }_{i} ( {w}_{1} - {w}_{i} )$$

We require that P be less than a specified target. Ideally, we want it to be exactly zero implying that the width of the conductor at any point along its length is constant. In practice it is seen that out-of-scope results i.e. P<0 are subjected to a progressively steep amplification, while in-scope results i.e. P>0 are subjected to a linear reduction so that as precision improves, the value of the loss function actually decreases.

### Component Loss Functions

Our discussion so far has been general without describing specific component loss functions, it merely being noted that the loss function comprises multiple component loss functions each configured to quantify a corresponding metric that serves as a measure of consistency over different tools despite physical tool differences. Inspection tools are equipped with a library of metrology algorithms, each customized for different measurements. As noted previously, each metrology algorithm has its own parameters that are defined by the end-user and serve to inform the metrology algorithm how to compute the desired measurement. In a typical setup, a user will select a required algorithm from a list of possible metrology algorithms provided by the manufacturer of the inspection tool, using a suitable graphical user interface, GUI. Not all metrology algorithms will necessarily make use of the same parameter set; and, of course, even to the extent that parameters may be common to different algorithms, their values will almost certainly be different between one algorithm and another. To this end, the manufacturer of the inspection tool will also store for each supported metrology algorithm a respective dataset of parameters and typically a range of pertinent values, and optionally a default value within the prescribed range that may serve as a reasonable choice to commence optimization.

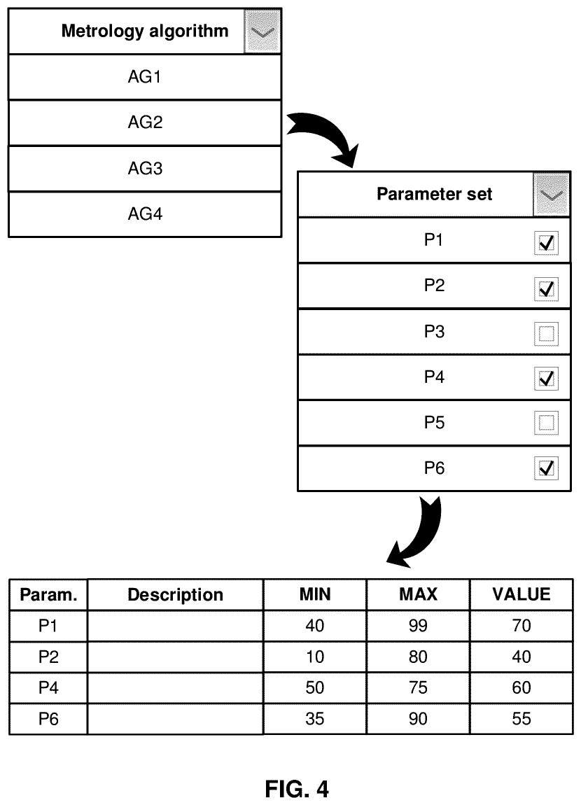

FIG. 4 shows schematically a typical GUI that allows the end-user to select a metrology algorithm and specify the parameters and their corresponding values to be used during optimization. A first dropdown includes a list of all metrology algorithms provided by the tool manufacturer, each being associated with a specific type of measurement and each having its own parameter set. Selection by the end-user of an algorithm e.g. AG2 displays a list of all the parameters associated therewith. Optimization may be performed by fine-tuning all the displayed parameters. But this is not mandatory and may not always be necessary. Therefore, associated with each parameter is a checkbox that allows the user to indicate whether or not the respective parameter is to be used. By way of example, we show that the user is interested in performing optimization with regard to parameters P1, P2, P4 and P6 but not with regard to P3 and P5. The selected parameters are now displayed together with a brief description indicating their functionality, a permitted range of values and a start value. For example, for P1 the permitted range is between 40-99 and the start value is 70. The start value is given a default value by the system but may be overridden by the end-user within the permitted range. The default value is part of the metrology algorithm library.

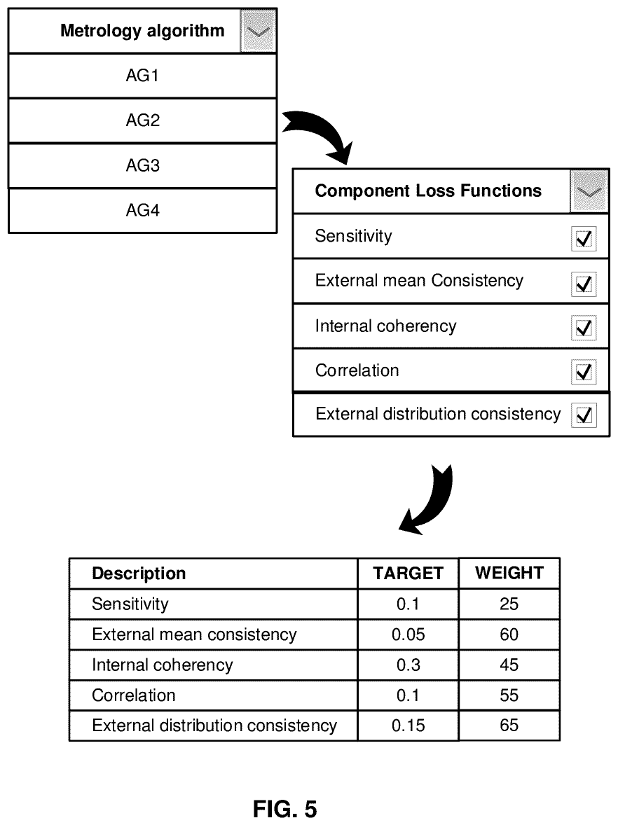

The parameter optimizer is interfaced to the selected metrology algorithm and receives therefrom (typically via a suitable API) the parameter set and the value of the aggregate loss function as shown in FIG. 1. Thus, with reference to FIG. 5, for the purpose of the parameter optimizer, it will receive a list of parameters, P1, P2, P4 and P6 and their respective initial values, 70, 40, 60, 55 as well as the permitted ranges within which to perform the optimization. The parameter optimizer will then adjust the actual values of the specified parameters until the value of the aggregate loss function is less than a specified (or default) value.

FIG. 5 shows schematically a graphical user interface for allowing selection of component loss functions and associated target values and weights. Upon selection of the metrology algorithm, there is displayed an associated list of component loss functions. The figure shows that which component loss functions are actually used is user-selectable. This may depend on the selected metrology algorithm and all displayed loss functions may alternatively be mandatory. For each operative loss function, the target value and relative weight may be specified by the end-user or may be set automatically. In use the weights are normalized so that each loss function contributes the desired fraction to the aggregate value.

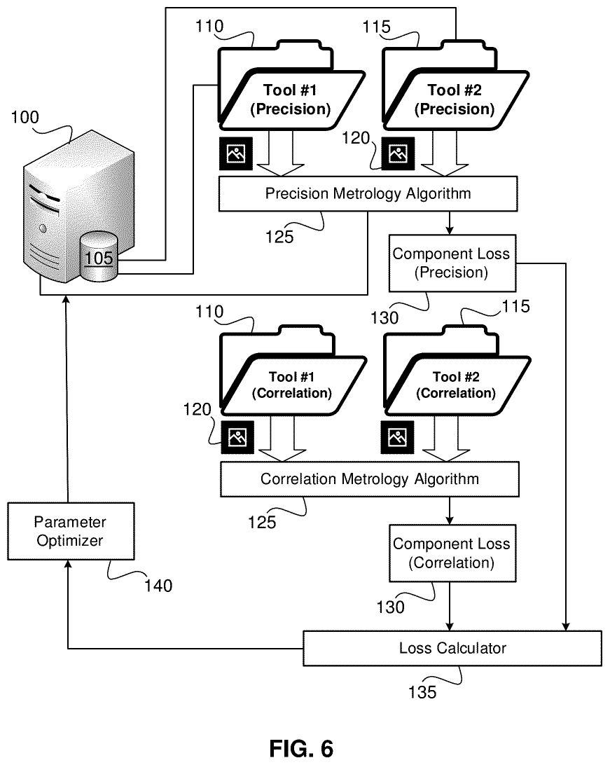

FIG. 6 shows schematically a standalone computer 100 according to an embodiment of the present disclosure configured to optimize parameters for a metrology algorithm. The computer 100 has a mass storage device 105 having a file structure organized into folders 110, 115 each storing multiple images 120 pertaining to a specific metrology algorithm 125, and further storing a component loss function 130 associated with the selected algorithm. Any given loss component function may, of course, be relevant to more than one algorithm. The mass storage device 105 stores a database storing a library of metrology algorithms and maps each metrology algorithm to its associated loss functions, although not all loss functions associated with a selected algorithm need to be selected by the user when running the optimization. Each metrology algorithm selected by the user extracts its images from the folder associated with the selected algorithm and selected loss functions. So, for example, as will become clearer from the following description of some of the loss functions, one loss function relates to precision providing a metric of similarity of repeated measurements of the same feature in the wafer. The metrology algorithm measures the critical dimension pertaining to that metrology algorithm of each image in the folder containing multiple images of the same feature, all of which should ideally have an identical measurement, but in practice are apt to deviate slightly. Likewise, another loss function relates to correlation providing a metric of similarity of measurements of the same feature in the wafer measured by two different tools. Corresponding images for each tool are stored in separate folders and the metrology algorithm measures the critical dimension pertaining to that metrology algorithm of each image in both folders, all pairs of which should ideally have an identical measurement, but in practice are apt to deviate slightly. The values for each selected component loss function 130 are summed by a loss function calculator 135, whose output is the aggregate loss and is fed to the parameter optimizer 140.

It will be understood that FIG. 6 shows a highly simplified example where two different loss functions are associated with different metrology algorithms. As noted above, in practice multiple loss functions are typically associated with each metrology algorithm and many of these loss functions will be common to more than one metrology algorithm. The arrangement of the images into folders and the mapping of the metrology algorithms to associated loss functions and of the loss functions to images is part of a pre-setup stage that is not itself part of the invention. It will be apparent that other arrangements and file structures may be employed to similar effect.

It should be noted that while we have described a typical implementation using a GUI, the parameters may be selected in other ways. For example, a voice recognition system can be employed allowing the user to select the metrology algorithm, loss functions and target values. Alternatively, these parameters may be preset according to the sample or the critical dimension being measured. They can be assigned in an initialization procedure that is carried out prior to performing optimization and stored together with the images or separately therefrom and formatted for acquisition by the metrology algorithm in a similar manner to that way it accesses the images.

It will be further understood that the functional elements shown in FIG. 6 are most typically implemented by software. In the case of a standalone system such as shown schematically in the figure, a suite of metrology algorithms and component loss functions may be stored on the computer 100 or, alternatively, may be stored on a remote server to which the computer has access. In a typical software implementation, a program receives as input measurements from the metrology algorithm together with one or more loss functions and associated target values and weights selected by the user as described above with reference to FIG. 5. It then computes a value of the total loss and sends it to the parameter optimizer. Each metrology algorithm may operate according to parameters initially selected by the user as described above with reference to FIG. 5 or otherwise specified, as noted previously. Regardless of how the initial parameters are assigned, each metrology algorithm is run multiple times, each time with the same image but with different parameters as assigned by the parameter optimizer, until an optimized result is obtained. This procedure may then be repeated for the same or another metrology algorithm using other images in the same image set and with other image sets, as required. It should also be noted that some or all of the functional elements shown in FIG. 6 may be provided in an enhanced inspection tool or in an integrated fleet of inspection tools. A fleet of inspection tools may be configured as a distributed system where software elements as described above are distributed between several different inspection tools. For example, each may have its own folders and be equipped with all the necessary metrology algorithms that are essential for measuring critical dimensions during manufacture. Parameter optimization can be performed in situ. If a component loss function is selected that requires comparing measurements of images stored in different inspection tools, the relevant file structure will need to be arranged and mapped in an initial setup procedure.

We shall now describe examples of component loss functions that may be provided, it being understood that the following list is illustrative and far from exhaustive:
Sensitivity (SENS):—a way to measure that changes in the object we are measuring are reflected in the results of the measurements (to avoid a situation where the consistency is preserved but the results do not reflect the actual materials). This function is generally derived for a known location where we have a valid estimation of the measurement and then compute the standard deviation of the remaining measurements relative to this known value. The distance from the known value reflects the sensitivity level.
External Mean Consistency (EMC)—given samples representing different tools we take samples from several tools of the same location. From the sample set we derive the mean value of all samples and the loss function is the sum of the respective distance of each of the samples from this value. In addition, for each structure we know the values which are considered reasonable (within the ballpark) and we give lower penalty to the function within this margin while giving a significant higher penalty to values exceeding this threshold.
Internal Coherency (IC)—This metric is used to assure that each of the tools individually when used repeatedly to measure the same physical structure returns similar results. This assures that each measurement by a single tool is reliable and avoids a situation of an average correctness with high variance. This metric is obtained by taking repeated measurements with each tool to thus derive a set of repetitions at different locations of the same structure. Then, measurements of outliers are detected and are treated in another scope. The remaining measurements are evaluated by a linear trend (due to the charging effect on this location) and the respective distance between the slope of the linear trend and each corresponding measurement is used as the loss.
Correlation to ground truth (CORR): trying to improve accuracy of measurement by comparing the measurement results obtained using different inspection tools that are obtained by using a set of parameters to a certain ground truth

$$C GT = min ( abs ( 1 - {R}^{2} ( m e a s - G T ) ) )$$

where:
meas—measurements obtained by using a specific set of parameters; and
GT—a known ground truth that is provided by the end-user.

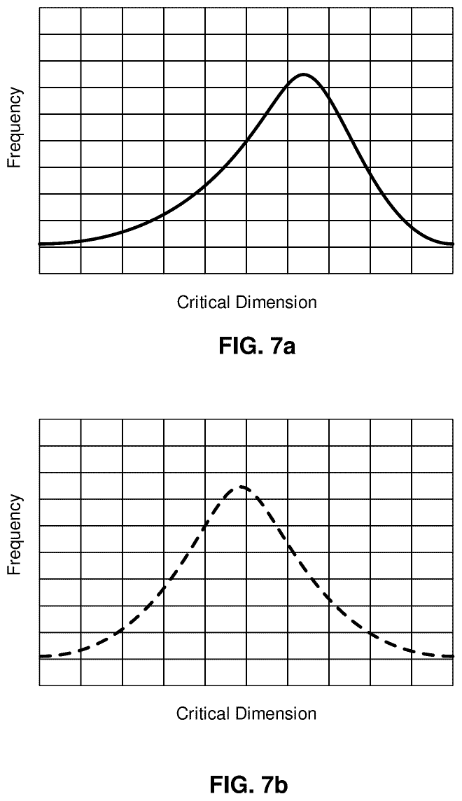

FIGS. 7a and 7b are graphical representations showing a pair of distributions of measurements of a given critical dimension versus the number of occurrences per measurement obtained using two different inspection tools, used as a matching metric according to a second embodiment of the invention. The scales are not dimensioned it being sufficient to note that both distributions are drawn to identical scales and are slightly mismatched. In use, respective measurements for multiple locations in an image set are obtained using two different inspection tools. This is done in conventional manner using a metrology algorithm to obtain measurements from the images. A metrology algorithm typically pertains to a specific metrology application. A metrology application refers to what a customer/user is interested to measure in general with respect to the specimen. By way of non-limiting example, a metrology application can be one of the following: Critical Dimension (CD) metrology, Overlay (OVL), Measurement-Based Inspection (MBI), and Critical Dimension Uniformity (CDU), etc. Our object is to optimize the metrology algorithm so that the same algorithm used by different inspection tools will produce similar or matching results. Although corresponding measurements may be obtained for each location thus creating two datasets having the same number of measurements such that corresponding measurements in each dataset relate to the same location, this is not a requirement. More generally, the two inspection tools may obtain measurements over similar locations. The locations do not need to be identical between tools, nor does the number of measurements obtained by each tool need to the same. From each dataset, we create respective distributions of the measurements for each of the two different tools, and use distribution-based metrics to measure similarity between the two distributions.

This metric, which we refer to as External Distribution Consistency and will denote by DIST, allows us to assure similarity of performance between different tools not only for the mean level but across a wider scope. In an embodiment of the invention reduced to practice, the Jensen-Shannon divergence function (JSD) was used as a metric for distribution differences. In probability theory and statistics, JSD is used to measure the similarity between two probability distributions. However, other distribution-based metrics may be used, such as Kullback Liebler (KL), Total Variation (TV), x², Hellinger distance (HL), Le cam distance (LC).

Regardless of which function is used, matching between inspection tools to obtain External Distribution Consistency offers significant benefits over conventional approaches such as Reference Correlation. One advantage of the DIST function over CORR is that CORR requires pairs of data samples from both tools on the same location and performs the comparison between each respective pair, while DIST creates a distribution across the complete range thereby encompassing locations that are not discretely provided for by CORR. More significantly, CORR is sensitive to disparities in a few locations, which can impose a large penalty even if there is good correlation for the vast majority of points in the dataset. DIST imposes a looser requirement for similarity since it is less sensitive to disparities in a few locations and instead gives a wider scope on the similarity over all sites. For example, at location A, tool_1 gives 3 and tool_2 gives 5, while at location B, tool_1 gives 5 and tool_2 gives 3. For CORR, the penalty increases for both locations while for DIST, the two locations compensate for each other. We observed that this approach is more effective for the optimization function since it allows the optimization algorithm to explore a wider range of parameter set even though it causes some penalty at specific locations. It will be understood that although the JSD measures the similarity between two distributions and therefore provides a metric for matching between two tools, the principle can be extended to multiple tools by applying the JSD (or any other suitable distribution-based metric) to successive pairs of tools as in {1, 2}, {1, 3}, {2, 3} {1, 4}, {2, 4}, {3, 4} etc.

Since different end-users have different areas of focus, we weight the above function in a way that best reflects the requirements, by adjusting the coefficients to derive the following loss function. A naïve way of formulating a loss function that takes all factors into account would be

$$Loss = {ω}_{1} \times SENS + {ω}_{2} \times E M C + {ω}_{3} \times I C + {ω}_{4} \times DIST + {ω}_{5} \times CORR$$

For example, if average consistency is the key factor, and the available reference is not fully reliable, we would overweight the EMC and DIST coefficients (i.e., ω₂ and ω₄) and would use smaller values for the SENS and CORR coefficients (i.e., ω₁ and ω₄). By “key factor” we mean that average consistency is the most important requirement, such that other metrics such as precision can be sacrificed (to some extent) in favor of consistency. This allows the end-user a measure of control over where to expend the most effort or resources in the optimization.

But as mentioned above, in one aspect of the present disclosure, we are using the amplification function (such as described above) to optimize the optimization function resulting in the following form:

$$Loss = {ω}_{1} \times u - ( SENS - SENS\_target ) + {ω}_{2} \times u - ( EMC - EMC\_target ) + {ω}_{3} \times u - ( IC - IC\_target ) + {ω}_{4} \times u - ( DIST - DIST\_target ) + {ω}_{5} \times u - ( CORR - CORR\_target )$$

### Automatic Weights

As noted above, the weights on may be assigned automatically.

In general, the larger the weight, the more significant its cost becomes in the total cost that is simply a weighted sum of all component losses.

There are three approaches how to set the weights correctly:

Prior knowledge of the typical component loss scores. In general, different component loss functions will produce different scores. For example, a typical IC score is ˜0.3 while a typical EMC score is ˜0.05. So, if these two component loss functions are given the same weight, the equation will not be balanced and the matching loss will be negligible as compared to the other loss, and therefore, practically, be ignored.

In this case, we will give a higher weight to the EMC loss function, to balance the equation.

Balance equation after first optimization trial. Sometimes prior knowledge of typical values is not sufficiently accurate, as the values can vary significantly between different cases. One solution is to run a first optimization trial with a nominal set of parameters, and then set the weights on after getting the scores of the different component loss functions.

Set weights according to distance from SPEC. In most cases a user tries to choose parameters that bring the results into SPEC, and each component loss function comes with its own SPEC. In this approach, weights are given according to two guidelines: 1) balancing equation and 2) giving a higher weight to a component loss function whose initial score as obtained by first optimization trial is not in SPEC (weight grows with the distance from SPEC).

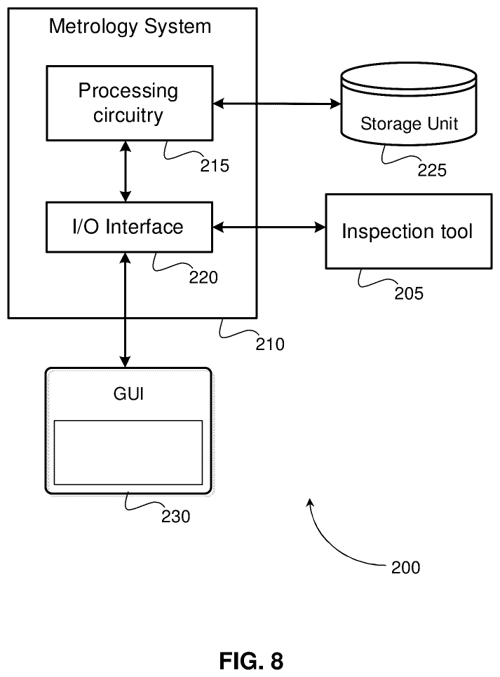

FIG. 8 shows some of the principal elements in an enhanced inspection system 200 according to an embodiment of the present disclosure used for inspection of a semiconductor specimen (e.g., a wafer, a die, or parts thereof) as part of the specimen fabrication process. As described above, the inspection referred to herein can be construed to cover any kind of operation related to defect inspection/detection, defect classification, segmentation, and/or metrology operations, such as, e.g., critical dimension (CD) measurements, roughness, overlay, etc., with respect to the specimen. System 200 comprises one or more inspection tools 205 configured to scan a specimen and capture images thereof to be further processed for various inspection applications.

The term “inspection tool” used herein should be expansively construed to cover any tool that can be used in inspection-related processes including, by way of non-limiting example, scanning (in a single or in multiple scans), imaging, sampling, reviewing, measuring, classifying and/or other processes provided with regard to the specimen or parts thereof.

According to certain embodiments of the presently disclosed subject matter, the inspection system 200 comprises a computer-implemented metrology system 210 operatively connected to the inspection tools 205 and capable of enabling automatic metrology operations with respect to a semiconductor specimen in runtime based on runtime images obtained during specimen fabrication.

Without limiting the scope of the disclosure in any way, it should also be noted that the inspection tool 205 can be implemented as inspection machines of various types, such as optical inspection machines, electron beam inspection machines (e.g., Scanning Electron Microscope (SEM), Atomic Force Microscopy (AFM), or Transmission Electron Microscope (TEM), etc.), and so on. In some cases, the same inspection tool can provide low-resolution image data and high-resolution image data. The resulting image data (low-resolution image data and/or high-resolution image data) can be transmitted directly or via one or more intermediate systems to the metrology system 210. The present disclosure is not limited to any specific type of inspection tool, nor with respect to the resolution of resulting image data.

According to certain embodiments, the metrology system 210 can be an electron beam tool, such as, e.g., scanning electron microscopy (SEM). SEM is a type of electron microscope that produces images of a specimen by scanning the specimen with a focused beam of electrons. The electrons interact with atoms in the specimen, producing various signals that contain information on the surface topography and/or composition of the specimen. SEM is capable of accurately measuring features during the manufacture of semiconductor wafers. By way of example, the metrology tool can be critical dimension scanning electron microscopes (CD-SEM) used to measure critical dimensions of structural features in the images.

The metrology system 210 includes processing circuitry 215 operatively connected to a hardware-based I/O interface 220 and configured to provide processing necessary for operating the system, as described above with particular reference to FIGS. 4, 5 and 6 of the drawings. The processing circuitry 215 can comprise one or more processors (not shown separately) and one or more memories (not shown separately). The one or more processors of the processing circuitry 215 can be configured, either separately or in any appropriate combination, to execute several functional modules in accordance with computer-readable instructions implemented on a non-transitory computer-readable memory that may form part of the processing circuitry. Such functional modules are referred to hereinafter as comprised in the processing circuitry.

The one or more processors referred to herein can represent one or more general-purpose processing devices such as a microprocessor, a central processing unit, or the like. More particularly, a given processor may be one of: a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. Each processor is configured to execute instructions for performing at least some of the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

In an initialization or setup procedure, the inspection tool 205 acquires a set of images capturing at least one site on the specimen with the given tool setting, thereby obtaining a plurality of sets of images that constitutes an image dataset and serve as input to an algorithm optimization such as shown schematically in FIG. 1. This procedure is done for multiple metrology algorithms that together form part of a metrology recipe, following which, the metrology system 210 is able to perform runtime metrology operations using the optimized metrology recipe.

Although an embodiment of the present invention relates to an enhanced inspection tool having integrated features for data generation and parameter optimization, it is important to clarify that the manner of image acquisition and data generation is not a feature of the present invention in its broadest context. For the sake of completeness, we describe image acquisition and data generation. But the manner in which the dataset is acquired is not important with regard to the data optimization, which is the principal focus of the present disclosure.

It is to be noted that while certain embodiments of the present disclosure refer to the processing circuitry 215 being configured to perform the above recited operations, the functionalities/operations of the aforementioned functional modules can be performed by the one or more processors in processing circuitry 215 in various ways. By way of example, the operations of each functional module can be performed by a specific processor, or by a combination of processors. The operations of the various functional modules, such as selecting a set of tool parameters, varying the value of each tool parameter, configuring the inspection tool, and optimizing the metrology algorithm, etc., can thus be performed by respective processors (or processor combinations) in the processing circuitry 215, while optionally, these operations may be performed by the same processor. The present disclosure should not be limited to being construed as one single processor always performing all the operations.

The system 200 comprises a storage unit 225 corresponding to the storage unit 105 shown in FIG. 6. The storage unit 225 can be configured to store any data necessary for operating the metrology system 210, e.g., data related to input and output of the metrology system 210, as well as intermediate processing results generated by the metrology system 210. By way of example, the storage unit 225 can be configured to store images of the specimen and/or derivatives thereof produced by the inspection tool 205. Accordingly, these input data can be retrieved from the storage unit 225 and provided to the processing circuitry 215 for further processing. The output of the metrology system 210, such as, e.g., the image dataset, and the optimized metrology algorithm, can be sent to storage unit 225 to be stored.

In some embodiments, the system 200 can optionally comprise a computer-based Graphical User Interface (GUI) 230 which is configured to enable user-specified inputs related to the metrology system 210 in a manner such as described above with reference to FIGS. 4 and 5 of the drawings.

Those versed in the art will readily appreciate that the teachings of the presently disclosed subject matter are not bound by the system illustrated in FIG. 8. Each system component and module in FIG. 8 can be made up of any combination of software, hardware and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules and functions than those shown in FIG. 8.

Each component in FIG. 8 may represent a plurality of the particular component, which are adapted to independently and/or cooperatively operate to process various data and electrical inputs, and for enabling operations related to a computerized inspection system. In some cases, multiple instances of a component may be utilized for reasons of performance, redundancy and/or availability. Similarly, in some cases, multiple instances of a component may be utilized for reasons of functionality or application. For example, different portions of the particular functionality may be placed in different instances of the component.

It should be noted that the inspection system illustrated in FIG. 8 can be implemented in a distributed computing environment, in which one or more of the aforementioned components and functional modules shown in FIG. 8 can be distributed over several local and/or remote devices. By way of example, the inspection tool 220 and the metrology system 210 can be located at the same entity (in some cases hosted by the same device) or distributed over different entities, depending on specific system configurations and implementation needs. In some examples, certain components utilize a cloud implementation, e.g., implemented in a private or public cloud. Communication between the various components of the inspection system, in cases where they are not located entirely in one location or in one physical entity, can be realized by any signaling system or communication components, modules, protocols, software languages and drive signals, and can be wired and/or wireless, as appropriate.

It should further be noted that in some embodiments at least some of inspection tools 205, storage unit 225 and/or GUI 230 can be external to the inspection system 200 and operate in data communication with systems 200 and 210 via the I/O interface 220. The metrology system 210 can be implemented as standalone computer(s) to be used in conjunction with the inspection tools, and/or with the additional inspection modules as described above. Alternatively, the respective functions of the metrology system 210 can, at least partly, be integrated with one or more inspection tools 205, thereby facilitating and enhancing the functionalities of the inspection tools 205 in inspection-related processes.

As the acquired image dataset depicts tool variations over time in a single tool or between different tools, it can be used to evaluate the metrology metric of matching, and optimize the metrology algorithm with respect to at least matching. Matching represents measurement variance between different tools (or of one tool over time), therefore is also referred to as tool matching, or tool-to-tool matching. Matching is related to the repeatability of measurement data from different images of the same given feature acquired by different tools. In some embodiments, the at least one metrology metric can further comprise one or more additional metrics, such as, e.g., precision, correlation and sensitivity, as will be described below.

As described above, a metrology algorithm typically comprises a large group of algorithm parameters characterizing the metrology algorithm. By way of example, the set of algorithm parameters can be selected based on user knowhow and experience. For instance, the selected set of algorithm parameters can include general parameters such as, e.g., smoothing, derivative size and type, etc., and/or many other custom-made algorithm parameters which pertain to a particular algorithm. Smoothing generally represents a low pass filter to be applied to the images. Derivative represents a high pass filter to be applied to the images.

The value of each algorithm parameter from the selected set can be varied a number of times, giving rise to a plurality of algorithm settings corresponding to a plurality of combinations of varying values of the set of algorithm parameters. By way of example, the value of a given parameter can be varied by a specified interval within a predefined range.

For each given algorithm setting of the plurality of algorithm settings, a plurality of sets of measurement data corresponding to the plurality of sets of images can be obtained using the metrology algorithm configured with the given algorithm setting. The plurality of sets of measurement data can be evaluated with respect to the at least one metrology metric. Once the plurality of algorithm settings are all traversed, and the respective sets of measurement data obtained thereof are evaluated, the metrology algorithm can be optimized based on the evaluation.

It is to be understood that the present disclosure is not limited in its application to the details set forth in the description contained herein or illustrated in the drawings.

In the present detailed description, numerous specific details are set forth in order to provide a thorough understanding of the disclosure. However, it will be understood by those skilled in the art that the presently disclosed subject matter may be practiced without these specific details. In other instances, well-known methods, procedures, components and circuits have not been described in detail so as not to obscure the presently disclosed subject matter.

Unless specifically stated otherwise, as apparent from the present discussions, it is appreciated that throughout the specification discussions utilizing terms such as “obtaining”, “examining”, “varying”, “configuring”, “acquiring”, “optimizing”, “using”, “selecting”, “evaluating”, “computing”, “verifying”, “meeting”, “tightening”, “identifying”, “combining”, or the like, refer to the action(s) and/or process(es) of a computer that manipulate and/or transform data into other data, said data represented as physical, such as electronic, quantities and/or said data representing the physical objects. The term “computer” should be expansively construed to cover any kind of hardware-based electronic device with data processing capabilities including, by way of non-limiting example, the inspection system, the metrology system, and respective parts thereof disclosed in the present application.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

The term “specimen” used in this specification should be expansively construed to cover any kind of physical objects or substrates including wafers, masks, reticles, and other structures, combinations and/or parts thereof used for manufacturing semiconductor integrated circuits, magnetic heads, flat panel displays, and other semiconductor-fabricated articles. A specimen is also referred to herein as a semiconductor specimen, and can be produced by manufacturing equipment executing corresponding manufacturing processes.

The term “inspection” used in this specification should be expansively construed to cover any kind of operations related to defect detection, defect review and/or defect classification of various types, segmentation, and/or metrology operations during and/or after the specimen fabrication process. Inspection is provided by using non-destructive inspection tools during or after manufacture of the specimen to be examined. By way of non-limiting example, the inspection process can include runtime scanning (in a single or in multiple scans), imaging, sampling, detecting, reviewing, measuring, classifying and/or other operations provided with regard to the specimen or parts thereof, using the same or different inspection tools. Likewise, inspection can be provided prior to manufacture of the specimen to be examined, and can include, for example, generating an inspection recipe(s) and/or other setup operations. It is noted that, unless specifically stated otherwise, the term “inspection” or its derivatives used in this specification are not limited with respect to resolution or size of an inspection area. A variety of non-destructive inspection tools includes, by way of non-limiting example, scanning electron microscopes (SEM), atomic force microscopes (AFM), optical inspection tools, etc.

The term “metrology operation” used in this specification should be expansively construed to cover any metrology operation procedure used to extract metrology information relating to one or more structural elements on a semiconductor specimen. In some embodiments, the metrology operations can include measurement operations, such as, e.g., critical dimension (CD) measurements performed with respect to certain structural elements on the specimen, including but not limiting to the following: dimensions (e.g., line widths, line spacing, contact diameters, size of the element, edge roughness, gray level statistics, etc.), shapes of elements, distances within or between elements, related angles, overlay information associated with elements corresponding to different design levels, etc. Measurement results such as measured images are analyzed, for example, by employing image-processing techniques. Note that, unless specifically stated otherwise, the term “metrology” or derivatives thereof used in this specification are not limited with respect to measurement technology, measurement resolution, or size of inspection area.

The term “defect” used in this specification should be expansively construed to cover any kind of abnormality or undesirable feature/functionality formed on a specimen. In some cases, a defect may be a defect of interest (DOI) which is a real defect that has certain effects on the functionality of the fabricated device, thus is in the customer's interest to be detected. For instance, any “killer” defects that may cause yield loss can be indicated as a DOI. In some other cases, a defect may be a nuisance (also referred to as “false alarm” defect) which can be disregarded because it has no effect on the functionality of the completed device and does not impact yield.

The term “design data” used in the specification should be expansively construed to cover any data indicative of hierarchical physical design (layout) of a specimen. Design data can be provided by a respective designer and/or can be derived from the physical design (e.g., through complex simulation, simple geometric and Boolean operations, etc.). Design data can be provided in different formats as, by way of non-limiting examples, GDSII format, OASIS format, etc. Design data can be presented in vector format, grayscale intensity image format, or otherwise.

The term “image(s)” or “image data” used in the specification should be expansively construed to cover any original images/frames of the specimen captured by an inspection tool during the fabrication process, derivatives of the captured images/frames obtained by various pre-processing stages, and/or computer-generated synthetic images (in some cases based on design data). Depending on the specific way of scanning (e.g., one-dimensional scan such as line scanning, two-dimensional scan in both x and y directions, or dot scanning at specific spots, etc.), image data can be represented in different formats, such as, e.g., as a gray level profile, a two-dimensional image, or discrete pixels, etc. It is to be noted that in some cases the image data referred to herein can include, in addition to images (e.g., captured images, processed images, etc.), numeric data associated with the images (e.g., metadata, hand-crafted attributes, etc.). It is further noted that images or image data can include data related to a processing step/layer of interest, or a plurality of processing steps/layers of a specimen.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. In the following detailed description, numerous specific details are set forth in order to provide a thorough understanding of the methods and apparatus.

It will also be understood that the system according to the present disclosure may be, at least partly, implemented on a suitably programmed computer. Likewise, the present disclosure contemplates a computer program being readable by a computer for executing the method of the present disclosure. The present disclosure further contemplates a non-transitory computer-readable memory tangibly embodying a program of instructions executable by the computer for executing the method of the present disclosure.

The present disclosure is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the present disclosure as hereinbefore described without departing from its scope, defined in and by the appended claims.

### Inventive Concepts

The following is a list of inventive concepts that emerge from the foregoing description:

Inventive concept 1: A system for optimizing a metrology algorithm used by an inspection tool, the system comprising:
a storage unit for storing at least one set of images, wherein each set captures a respective site on the wafer and includes different images obtained using different tools or different tool settings,
a processing unit configured to run a specified metrology algorithm multiple times, each time with a different respective set of input parameters to obtain multiple measurements each pertaining to the respective specific feature for each image in a set of images;
said processing unit being responsive to one or more target measurements each relating to a respective component loss function, Mᵢ for computing a respective value of each component loss function wherein each target indicates whether the respective measurement falls within a prescribed range with respect to a metrology metric relating to said component loss function;
a loss calculator for computing an aggregate loss function of the form:

$$Loss = {\sum }_{i} {ω}_{i} \cdot {M}_{i}$$

wherein one of the component loss functions relates to tool matching; and
ωᵢ is a coefficient; and
a parameter optimizer responsive to a value of the aggregate loss function for optimizing the metrology algorithm to obtain an optimal set of input parameters, which when applied to the metrology algorithm produces measurements that are consistent when made by a single inspection tool of a given type or by different inspection tools of the same given type; and
wherein the loss calculator is configured to amplify each component loss function Mᵢ by a non-linear function that compares an actual value of the component loss function Mᵢ with the respective target measurement and applies a positive gain for in-range measurements whose difference from the respective target measurement is less than a prescribed threshold, while for out-of-range measurements whose difference from the respective target measurement exceeds said threshold, applies a steep penalty that swamps any cumulative gains associated with other component loss functions.

Inventive concept 2: The system according to inventive concept 1, wherein the non-linear function is of the form

$${\overline{u}}_{( x )} = \{ \begin{matrix}2 x ( 1 - {e}^{( cx )} ) + {xe}^{( cx )} & x > 0 \\ x & x < 0\end{matrix} \}$$

where x represents the difference between a component function and a desired goal.

Inventive concept 3: The system according to inventive concept 1 or 2, wherein the coefficient ωᵢ defines a relative importance of the respective component loss function within the loss function such that the higher the value of ωᵢ the more effort is exerted by the optimization process to minimize the respective component loss function.

Inventive concept 4: The system according to any one of inventive concepts 1 to 3, wherein the coefficient ωᵢ are entered manually via the user-interface.

Inventive concept 5: The system according to any one of inventive concepts 1 to 4, wherein the target measurements are entered manually via the user-interface.

Inventive concept 6: The system according to any one of inventive concepts 1 to 5, being a programmed computer.

Inventive concept 7: The system according to any one of inventive concepts 1 to 5, being coupled to or integrated within a metrology system.

Inventive concept 8: A system for optimizing a metrology algorithm used by an inspection tool, the system comprising:
a storage unit for storing at least one set of images, wherein each set captures a respective site on the wafer and includes different images obtained using different tools or different tool settings,
a processing unit configured to run a specified metrology algorithm multiple times, each time with a different respective set of input parameters to obtain multiple measurements each pertaining to the respective specific feature for each set of images;
said processing unit being responsive to one or more target measurements each relating to a respective component loss function, Mᵢ for computing a respective value of each component loss function wherein each target indicates whether the respective measurement falls within a prescribed range with respect to a metrology metric relating to said component loss function;
a loss calculator for computing an aggregate loss function of the form:

$$Loss = {\sum }_{i} {ω}_{i} \cdot {M}_{i}$$

wherein one of the component loss functions relates to tool matching; and
ωᵢ is a coefficient; and
a parameter optimizer responsive to a value of the aggregate loss function for optimizing the metrology algorithm to obtain an optimal set of input parameters, which when applied to the metrology algorithm produces measurements that are consistent when made by a single inspection tool of a given type or by different inspection tools of the same given type; and
wherein the loss calculator is configured to:
obtain respective measurements for multiple locations across two different tools;
create respective distributions of the measurements for each of the two different tools; and
use distribution-based metrics to measure similarity between the two distributions.

Inventive concept 9: The system according to inventive concept 8, wherein the coefficient ωᵢ defines a relative importance of the respective component loss function within the loss function such that the higher the value of ωᵢ the more effort is exerted by the optimization process to minimize the respective component loss function.

Inventive concept 10: The system according to inventive concept 8 or 9, wherein the measurements include corresponding measurements taken at a same or similar location for each tool.

Inventive concept 11: The system according to any one of inventive concepts 8 to 10, wherein the distribution-based metrics are based on any one in the group consisting of {Jensen-Shannon Divergence (JSD), Kullback Liebler (KL), Total Variation (TV), x², Hellinger distance (HL), Le cam distance (LC)}.

Inventive concept 12: The system according to any one of inventive concepts 8 to 11, wherein the component loss functions define one or more of the following:
sensitivity defining a way to measure that changes in the object we are measuring are reflected in the results of the measurements;
external mean consistency i.e. matching given samples representing different tools we take samples from several tools of the same location;
internal coherency configured to assure that each of the tools returns similar results when measuring an identical physical structure;
external distribution consistency used to assure similarity of performance between different tools not only for the mean level but across a wider scope;
reference correlation used to compute a linear regression between the reference and the results obtained using the parameters.

Inventive concept 13: A computerized method for optimizing a metrology algorithm used by an inspection tool, the method comprising:
acquiring at least one set of images, wherein each set captures a respective site on the wafer and includes different images obtained using different tools or different tool settings,
for each specific feature common to image in the set of images for which a measurement is required, running the metrology algorithm multiple times, each time with a different respective set of input parameters to obtain multiple measurements each pertaining to the respective specific feature;
for each measurement, providing one or more target measurements, each target measurement relating to a component loss function, Mᵢ that indicates whether each measurement falls within a prescribed range with respect to a metrology metric relating to said component loss function;
defining an aggregate loss function of the form:

$$Loss = {\sum }_{i} {ω}_{i} \cdot {M}_{i}$$

wherein one of the component loss functions relates to tool matching; and
ωᵢ is a coefficient; and
optimizing the metrology algorithm to obtain an optimal set of input parameters, which when applied to the metrology algorithm produces measurements that are consistent when made by a single inspection tool of a given type or by different inspection tools of the same given type;
wherein optimizing the metrology algorithm includes:
amplifying each component loss function Mᵢ by a non-linear function that compares an actual value of the component loss function Mᵢ with the respective target measurement and applies a positive gain for in-range measurements whose difference from the respective target measurement is less than a prescribed threshold, while for out-of-range measurements whose difference from the respective target measurement exceeds said threshold, applies a steep penalty that swamps any cumulative gains associated with other component loss functions.

Inventive concept 14: The method according to inventive concept 13, wherein the non-linear function is of the form

$${\overline{u}}_{( x )} = \{ \begin{matrix}2 x ( 1 - {e}^{( cx )} ) + {xe}^{( cx )} & x > 0 \\ x & x < 0\end{matrix} \}$$

where x represents the difference between a component function and a desired goal.

Inventive concept 15: The method according to inventive concept 13 or 14, wherein the coefficient ωᵢ defines a relative importance of the respective component loss function within the loss function such that the higher the value of ωᵢ the more effort is exerted by the optimization process to minimize the respective component loss function.

Inventive concept 16: The method according to any one of inventive concepts 13 to 15, wherein the component loss functions define one or more of the following:
sensitivity defining a way to measure that changes in the object we are measuring are reflected in the results of the measurements;
external mean consistency i.e. matching given samples representing different tools we take samples from several tools of the same location;
internal coherency configured to assure that each of the tools returns similar results when measuring an identical physical structure;
external distribution consistency used to assure similarity of performance between different tools not only for the mean level but across a wider scope;
reference correlation used to compute a linear regression between the reference and the results obtained using the parameters.

Inventive concept 17: A computerized method for optimizing a metrology algorithm used by an inspection tool, the method comprising:
acquiring at least one set of images, wherein each set captures a respective site on the wafer and includes different images obtained using different tools or different tool settings;
for each specific feature common to each image in the set of images for which a measurement is required, running the metrology algorithm multiple times, each time with a different respective set of input parameters to obtain multiple measurements each pertaining to the respective specific feature;
for each measurement, providing one or more target measurements, each target measurement relating to a component loss function, Mᵢ that indicates whether each measurement falls within a prescribed range with respect to a metrology metric relating to said component loss function;
defining a loss function of the form:

$$Loss = {\sum }_{i} {ω}_{i} \cdot {M}_{i}$$

wherein one of the component loss functions relates to tool matching; and
ωᵢ is a coefficient; and
optimizing the metrology algorithm to obtain an optimal set of input parameters, which when applied to the metrology algorithm produces measurements that are consistent when made by said inspection tool or by different inspection tools of similar type;
wherein optimizing the metrology algorithm includes:
obtaining respective measurements for multiple locations across two different tools;
creating respective distributions of the measurements for each of the two different tools; and
using distribution-based metrics to measure similarity between the two distributions.

Inventive concept 18: The method according to inventive concept 17, wherein the coefficient ωᵢ defines a relative importance of the respective component loss function within the loss function such that the higher the value of ωᵢ the more effort is exerted by the optimization process to minimize the respective component loss function.

Inventive concept 19: The method according to inventive concept 17 or 18, wherein the measurements include corresponding measurements taken at a same or similar location for each tool.

Inventive concept 20: The method according to any one of inventive concepts 17 to 19, wherein the distribution-based metrics are based on any one in the group consisting of {Jensen-Shannon Divergence (JSD), Kullback Liebler (KL), Total Variation (TV), x², Hellinger distance (HL), Le cam distance (LC)}.

Inventive concept 21: The method according to any one of inventive concepts 17 to 20, wherein the component loss functions define one or more of the following:
sensitivity defining a way to measure that changes in the object we are measuring are reflected in the results of the measurements;
external mean consistency i.e. matching given samples representing different tools we take samples from several tools of the same location;
internal coherency configured to assure that each of the tools returns similar results when measuring an identical physical structure;
external distribution consistency used to assure similarity of performance between different tools not only for the mean level but across a wider scope;
reference correlation used to compute a linear regression between the reference and the results obtained using the parameters.

Inventive concept 22: A computer program product comprising a non-transitory computer readable medium storing program code, which, when executed by a computer processor, carries out the method according to any one of inventive concepts 13 to 16.

Inventive concept 23: A computer program product comprising a non-transitory computer readable medium storing program code, which, when executed by a computer processor, carries out the method according to any one of inventive concepts 17 to 21.

1. A system for optimizing a metrology algorithm used by an inspection tool, the system comprising:
a storage unit for storing at least one set of images, wherein each set captures a respective site on the wafer and includes different images obtained using different tools or different tool settings,
a processing unit configured to run a specified metrology algorithm multiple times, each time with a different respective set of input parameters to obtain multiple measurements each pertaining to the respective specific feature for each image in a set of images;
said processing unit being responsive to one or more target measurements each relating to a respective component loss function, Mᵢ for computing a respective value of each component loss function wherein each target indicates whether the respective measurement falls within a prescribed range with respect to a metrology metric relating to said component loss function;
a loss calculator for computing an aggregate loss function of the form:
$$Loss = {\sum }_{i} {ω}_{i} \cdot {M}_{i}$$
wherein one of the component loss functions relates to tool matching; and
ωᵢ is a coefficient; and
a parameter optimizer responsive to a value of the aggregate loss function for optimizing the metrology algorithm to obtain an optimal set of input parameters, which when applied to the metrology algorithm produces measurements that are consistent when made by a single inspection tool of a given type or by different inspection tools of the same given type; and
wherein the loss calculator is configured to amplify each component loss function Mᵢ by a non-linear function that compares an actual value of the component loss function Mᵢ with the respective target measurement and applies a positive gain for in-range measurements whose difference from the respective target measurement is less than a prescribed threshold, while for out-of-range measurements whose difference from the respective target measurement exceeds said threshold, applies a steep penalty that swamps any cumulative gains associated with other component loss functions.

2. The system according to claim 1, wherein the non-linear function is of the form
$${\overline{u}}_{( x )} = \{ \begin{matrix}2 x ( 1 - {e}^{( cx )} ) + {xe}^{( cx )} & x > 0 \\ x & x < 0\end{matrix} \}$$
where x represents the difference between a component function and a desired goal.

3. The system according to claim 1, wherein the coefficient ωᵢ defines a relative importance of the respective component loss function within the loss function such that the higher the value of w) the more effort is exerted by the optimization process to minimize the respective component loss function.

4. The system according to claim 1, wherein the coefficient ωᵢ are entered manually via the user-interface.

5. The system according to claim 1, wherein the target measurements are entered manually via the user-interface.

6. The system according to claim 1, being a programmed computer.

7. The system according to claim 1, being coupled to or integrated within a metrology system.

8. A computerized method for optimizing a metrology algorithm used by an inspection tool, the method comprising:
acquiring at least one set of images, wherein each set captures a respective site on the wafer and includes different images obtained using different tools or different tool settings,
for each specific feature common to each image in the set of images for which a measurement is required, running the metrology algorithm multiple times, each time with a different respective set of input parameters to obtain multiple measurements each pertaining to the respective specific feature;
for each measurement, providing one or more target measurements, each target measurement relating to a component loss function, Mᵢ that indicates whether each measurement falls within a prescribed range with respect to a metrology metric relating to said component loss function;
defining an aggregate loss function of the form:
$$Loss = {\sum }_{i} {ω}_{i} \cdot {M}_{i}$$
wherein one of the component loss functions relates to tool matching; and
ωᵢ is a coefficient; and
optimizing the metrology algorithm to obtain an optimal set of input parameters, which when applied to the metrology algorithm produces measurements that are consistent when made by a single inspection tool of a given type or by different inspection tools of the same given type;
wherein optimizing the metrology algorithm includes:
amplifying each component loss function Mᵢ by a non-linear function that compares an actual value of the component loss function Mᵢ with the respective target measurement and applies a positive gain for in-range measurements whose difference from the respective target measurement is less than a prescribed threshold, while for out-of-range measurements whose difference from the respective target measurement exceeds said threshold, applies a steep penalty that swamps any cumulative gains associated with other component loss functions.

9. The method according to claim 8, wherein the non-linear function is of the form
$${\overline{u}}_{( x )} = \{ \begin{matrix}2 x ( 1 - {e}^{( cx )} ) + {xe}^{( cx )} & x > 0 \\ x & x < 0\end{matrix} \}$$
where x represents the difference between a component function and a desired goal.

10. The method according to claim 8, wherein the coefficient ωᵢ defines a relative importance of the respective component loss function within the loss function such that the higher the value of ωᵢ the more effort is exerted by the optimization process to minimize the respective component loss function.

11. The method according to claim 8, wherein the component loss functions define one or more of the following:
sensitivity defining a way to measure that changes in the object we are measuring are reflected in the results of the measurements;
external mean consistency i.e. matching given samples representing different tools we take samples from several tools of the same location;
internal coherency configured to assure that each of the tools returns similar results when measuring an identical physical structure;
external distribution consistency used to assure similarity of performance between different tools not only for the mean level but across a wider scope;
reference correlation used to compute a linear regression between the reference and the results obtained using the parameters.

12. A computerized method for optimizing a metrology algorithm used by an inspection tool, the method comprising:
acquiring at least one set of images, wherein each set captures a respective site on the wafer and includes different images obtained using different tools or different tool settings;
for each specific feature common to each image in the set of images for which a measurement is required, running the metrology algorithm multiple times, each time with a different respective set of input parameters to obtain multiple measurements each pertaining to the respective specific feature;
for each measurement, providing one or more target measurements, each target measurement relating to a component loss function, Mᵢ that indicates whether each measurement falls within a prescribed range with respect to a metrology metric relating to said component loss function;
defining a loss function of the form:
$$Loss = {\sum }_{i} {ω}_{i} \cdot {M}_{i}$$
wherein one of the component loss functions relates to tool matching; and
ωᵢ is a coefficient; and
optimizing the metrology algorithm to obtain an optimal set of input parameters, which when applied to the metrology algorithm produces measurements that are consistent when made by said inspection tool or by different inspection tools of similar type;
wherein optimizing the metrology algorithm includes:
obtaining respective measurements for multiple locations across two different tools;
creating respective distributions of the measurements for each of the two different tools; and
using distribution-based metrics to measure similarity between the two distributions.

13. The method according to claim 12, wherein the coefficient ωᵢ defines a relative importance of the respective component loss function within the loss function such that the higher the value of ωᵢ the more effort is exerted by the optimization process to minimize the respective component loss function.

14. The method according to claim 12, wherein the measurements include corresponding measurements taken at a same or similar location for each tool.

15. The method according to claim 12, wherein the distribution-based metrics are based on any one in the group consisting of {Jensen-Shannon Divergence (JSD), Kullback Liebler (KL), Total Variation (TV), x², Hellinger distance (HL), Le cam distance (LC)}.

16. The method according to claim 12, wherein the component loss functions define one or more of the following:
sensitivity defining a way to measure that changes in the object we are measuring are reflected in the results of the measurements;
external mean consistency i.e. matching given samples representing different tools we take samples from several tools of the same location;
internal coherency configured to assure that each of the tools returns similar results when measuring an identical physical structure;
external distribution consistency used to assure similarity of performance between different tools not only for the mean level but across a wider scope;
reference correlation used to compute a linear regression between the reference and the results obtained using the parameters.

17. A computer program product comprising a non-transitory computer readable medium storing program code, which, when executed by a computer processor, carries out the method according to claim 8.

18. A computer program product comprising a non-transitory computer readable medium storing program code, which, when executed by a computer processor, carries out the method according to claim 12.
